(19) United States
(12) Patent Application Publication
(10) Pub. No.: US 2025/0107398 A1
(43) Pub. Date: Mar. 27, 2025

(54) DISPLAY DEVICE AND METHOD FOR MANUFACTURING THE DISPLAY DEVICE

(71) Applicant: Samsung Display Co., LTD., Yongin-si (KR)

(72) Inventors: In Seok SEO, Yongin-si (KR); Han Sol KANG, Yongin-si (KR); Jung Ho PARK, Yongin-si (KR); Seung Hwan CHUNG, Yongin-si (KR)

(21) Appl. No.: 18/669,348

(22) Filed: May 20, 2024

(30) Foreign Application Priority Data
Sep. 22, 2023 (KR) 10-2023-0127492

(51) Int. Cl. H10K 59/80; H10K 102/00

(52) U.S. Cl. CPC H10K 59/8722; H10K 2102/311

(57) ABSTRACT

A display device includes: a display panel including a folding area and a non-folding area on one side of the folding area; and an upper protective member on a first surface of the display panel and including a coating layer, wherein the coating layer includes: a first portion overlapping the folding area; and a second portion on one side of the first portion, wherein a contact angle of the first portion is different from a contact angle of the second portion.

### CROSS-REFERENCE TO RELATED APPLICATION

The present application claims priority to and the benefit of Korean Patent Application No. 10-2023-0127492, filed on Sep. 22, 2023, in the Korean Intellectual Property Office, the entire disclosure of which is incorporated herein by reference.

### BACKGROUND

### 1. Field

Aspects of some embodiments of the present disclosure relate to a display device and a method for manufacturing the display device.

### 2. Description of the Related Art

As an information society develops, the demand for a display device for displaying an image is increasing in various forms. For example, the display device has been applied to various electronic devices such as smartphones, digital cameras, laptop computers, navigation devices, and smart televisions.

In order to increase the portability of display devices and provide a wider display screen, a bendable display device with a bendable display area or a foldable display device with a foldable display area has recently been released.

The above information disclosed in this Background section is only for enhancement of understanding of the background and therefore the information discussed in this Background section does not necessarily constitute prior art.

### SUMMARY

Aspects of some embodiments of the present disclosure include a display device that may relatively improve an adhesive force of a portion of a coating layer of an upper protective member, and a method for manufacturing the display device.

Aspects of some embodiments of the present disclosure include a display device that may minimize or reduce a lifting phenomenon of a cover window, and a method for manufacturing the display device.

However, aspects of embodiments according to the present disclosure are not restricted to those set forth herein. The above and other aspects of embodiments according to the present disclosure will become more apparent to one of ordinary skill in the art to which the present disclosure pertains by referencing the detailed description of the present disclosure given below.

According to some embodiments of the present disclosure, a display device includes, a display panel including a folding area and a non-folding area on one side of the folding area, and an upper protective member on a first surface of the display panel and including a coating layer, wherein the coating layer includes, a first portion overlapping the folding area, and a second portion on one side of the first portion, wherein a contact angle of the first portion is different from a contact angle of the second portion.

According to some embodiments, the contact angle of the first portion is smaller than the contact angle of the second portion.

According to some embodiments, the contact angle of the first portion is 90 degrees to 105 degrees.

According to some embodiments, the contact angle of the second portion is 110 degrees or more.

According to some embodiments, the display device may further comprise, a cover window on the upper protective member, and an adhesive member between the cover window and the upper protective member, wherein a first adhesive force, which is an adhesive force between the first portion and the adhesive member, is different from a second adhesive force, which is an adhesive force between the second portion and the adhesive member.

According to some embodiments, the first adhesive force is greater than the second adhesive force.

According to some embodiments, the first adhesive force is 3 to 8 times the second adhesive force.

According to some embodiments, the display device may further comprise a panel support member on a second surface of the display panel, wherein the panel support member includes a folding portion in the folding area and a non-folding portion in the non-folding area, and wherein a width of the first portion is greater than a width of the folding portion.

According to some embodiments, the upper protective member includes at least one of polyacrylate, polyethylene terephthalate, polyimide, cycloolefin polymer, triacetyl cellulose, polycarbonate, epoxy, or polymethyl methacrylate.

According to some embodiments, the upper protective member has a transmittance of 85% or more and a haze of 2% or less.

According to some embodiments, the coating layer includes at least one of a silicone-based material, an acrylic-based material, an epoxy-based material, or polyurethane.

According to some embodiments, the coating layer includes an AF additive.

According to some embodiments, a thickness of the upper protective member is 200 μm or less.

According to some embodiments, a thickness of the coating layer is 1 μm to 20 μm.

According to some embodiments of the present disclosure, there is provided a display device including, a display panel, an upper protective member on the display panel and including a coating layer, and a cover window on the upper protective member, wherein the coating layer includes a first portion and a second portion on one side of the first portion, wherein the cover window is bent in an area overlapping the first portion, and wherein a contact angle of the first portion is different from a contact angle of the second portion.

According to some embodiments, the contact angle of the first portion is smaller than the contact angle of the second portion.

According to some embodiments of the present disclosure, there is provided a method for manufacturing a display device, the method including, providing an upper protective member including a coating layer, and performing plasma treatment on a first portion of the coating layer excluding a second portion of the coating layer, wherein a contact angle of the first portion is different from a contact angle of the second portion.

According to some embodiments, in the performing of the plasma treatment, a relative velocity between a plasma treatment head and the coating layer is 3 m/min to 8 m/min.

According to some embodiments, the contact angle of the first portion is smaller than the contact angle of the second portion.

According to some embodiments, the coating layer is formed by a roll to roll process.

In a display device and the method for manufacturing the display device according to some embodiments of the present disclosure, the adhesive force of a portion of the coating layer of the upper protective member may be relatively improved.

In a display device and the method for manufacturing the display device according to some embodiments of the present disclosure, the lifting phenomenon of the cover window may be minimized or reduced.

However, the characteristics of embodiments according to the present disclosure are not restricted to those specifically set forth herein. The above and other characteristics of the embodiments will become more apparent to one of daily skill in the art to which the embodiments pertain by referencing the claims.

### BRIEF DESCRIPTION OF DRAWINGS

The above and other characteristics of embodiments according to the present disclosure will become more apparent by describing in more detail aspects of some embodiments thereof with reference to the attached drawings, in which:

FIG. 1 is a perspective view illustrating a state in which a display device according to some embodiments is unfolded;

FIG. 2 is a perspective view illustrating a state in which a display device according to some embodiments is folded;

FIG. 3 is a perspective view illustrating a state in which a display device according to some embodiments is unfolded;

FIG. 4 is a perspective view illustrating a state in which a display device according to some embodiments is folded;

FIG. 5 is an exploded perspective view illustrating a display device according to some embodiments;

FIG. 6 is a cross-sectional view taken along the line X1-X1′ of FIG. 5;

FIG. 7 is a view illustrating an example of a display panel according to some embodiments;

FIG. 8 is a perspective view illustrating a panel support member according to some embodiments;

FIG. 9 is a perspective view illustrating an upper protective member according to some embodiments;

FIG. 10 is a plan view illustrating a coating layer according to some embodiments;

FIG. 11 is a cross-sectional view illustrating some layers of a display device according to some embodiments;

FIG. 12 is a flowchart illustrating a method for manufacturing a display device according to some embodiments;

FIG. 13 is a perspective view illustrating aspects of an example operation S100 of FIG. 12;

FIG. 14 is a cross-sectional view taken along the line X2-X2′ of FIG. 13;

FIG. 15 is a perspective view illustrating aspects of an example operation S200 of FIG. 12;

FIG. 16 is a cross-sectional view taken along the line X3-X3′ of FIG. 15;

FIG. 17 is a perspective view illustrating aspects of an example operation S300 of FIG. 12;

FIG. 18 is a cross-sectional view taken along the line X4-X4′ of FIG. 17;

FIG. 19 is a cross-sectional view taken along the line X5-X5′ of FIG. 17;

FIG. 20 is a perspective view illustrating aspects of an example operation S400 of FIG. 12; and

FIG. 21 is a cross-sectional view taken along the line X6-X6′ of FIG. 20.

### DETAILED DESCRIPTION

Aspects of some embodiments of the present disclosure will now be described more fully hereinafter with reference to the accompanying drawings, in which aspects of some embodiments of the present disclosure are shown. This invention may, however, be embodied in different forms and should not be construed as limited to the embodiments set forth herein. Rather, these embodiments are provided so that this disclosure will be thorough and complete, and will filly convey the scope of the invention to those skilled in the art.

It will also be understood that when a layer is referred to as being “on” another layer or substrate, it can be directly on the other layer or substrate, or intervening layers may also be present. The same reference numbers indicate the same components throughout the specification.

Hereinafter, embodiments of the present disclosure will be described in more detail with reference to the accompanying drawings.

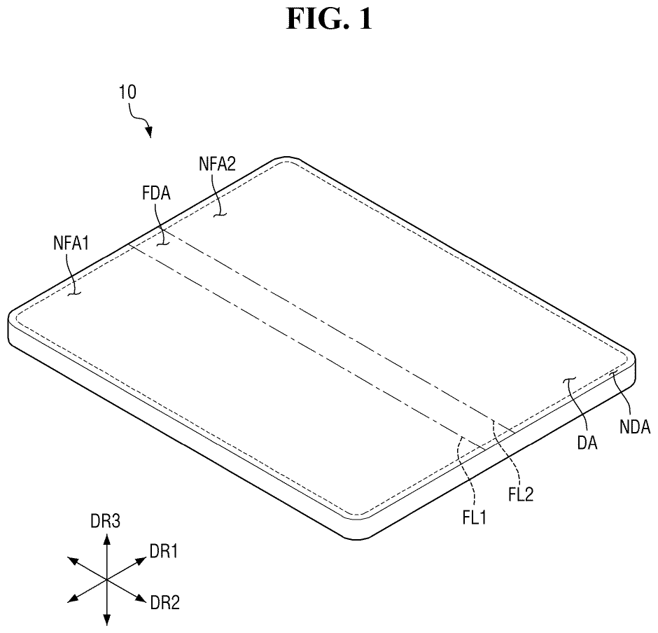

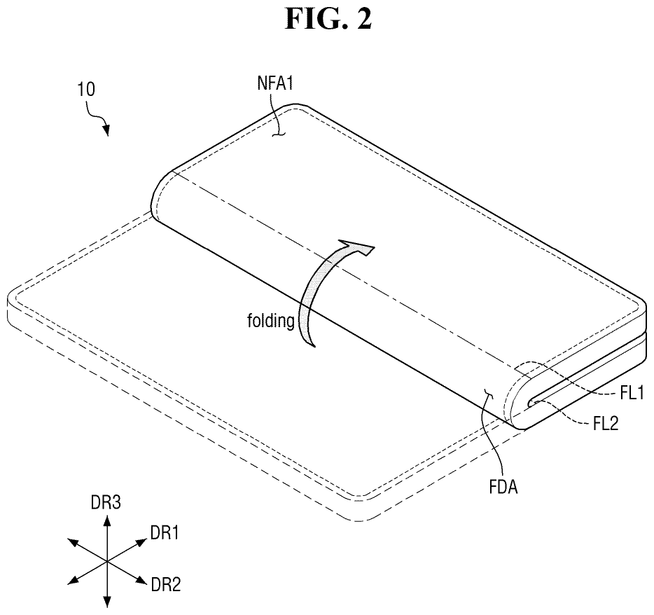

FIG. 1 is a perspective view illustrating a state in which a display device according to some embodiments is unfolded. FIG. 2 is a perspective view illustrating a state in which a display device according to some embodiments is folded.

Referring to FIGS. 1 and 2, FIG. 1 illustrates a first state of a display device 10 in which the display device 10 is unfolded without being folded at folding lines FL1 and FL2, and FIG. 2 illustrates a second state of the display device 10 in which the display device 10 is folded at the folding lines FL1 and FL2.

The display device 10 according to some embodiments is a device that displays a moving image or a still image, and may be used as a display screen of each of various products such as a television, a laptop computer, a monitor, a billboard, and Internet of Things (IoT) as well as portable electronic devices such as a mobile phone, a smartphone, a tablet personal computer (PC), a smartwatch, a watch phone, a mobile communication terminal, an electronic organizer, an electronic book, a portable multimedia player (PMP), a navigation device, and an ultra mobile PC (UMPC).

In the drawings, a first direction DR1 may be a direction parallel to one side of the display device 10 when viewed on a plane (or in a plan view), for example, a horizontal direction of the display device 10. A second direction DR2 may be a direction parallel to the other side in contact with one side of the display device 10 when viewed on a plane (or in a plan view), and may be a vertical direction of the display device 10. A third direction DR3 may be a thickness direction of the display device 10 (or a direction that is perpendicular or normal with respect to a plane defined by the first direction DR1 and the second direction DR2 or a plane of a display surface in FIG. 1).

A planar shape of the display device 10 may be a quadrangular shape such as a rectangle. Each corner of the display device 10 may have a right-angled planar shape or a round planar shape. The front surface of the display device 10 may include two short sides arranged in the first direction DR1 and two long sides arranged in the second direction DR2.

The display device 10 may include a display area DA and a non-display area NDA. A planar shape of the display area DA may follow the shape of the display device 10. For example, when the planar shape of the display device 10 is a rectangle, the planar shape of the display area DA may also be a rectangle.

The display area DA may be an area including a plurality of pixels to display an image. The non-display area NDA may be an area that does not include the pixels and does not display the image. The non-display area NDA may be arranged around the display area DA. The non-display area NDA may be arranged to surround the display area DA, but the embodiments of the present disclosure are not limited thereto. The display area DA may be partially surrounded by the non-display area NDA.

The display device 10 may maintain both the first state in which the display device 10 is unfolded and the second state in which the display device 10 is folded. According to some embodiments, the display device 10 may be folded in an in-folding manner so that the display areas DA face each other, as illustrated in FIG. 2. In this case, the front surfaces of the display devices 10 may face each other when folded. According to some embodiments, the display devices 10 may be folded in an out-folding manner so that the back surfaces thereof face each other.

The display device 10 may include a folding area FDA, a first non-folding area NFA1, and a second non-folding area NFA2. The folding area FDA may be an area in which the display device 10 is bent or folded, and the first non-folding area NFA1 and the second non-folding area NFA2 may be areas in which the display device 10 is not bent or folded. According to some embodiments, the first non-folding area NFA1 and the second non-folding area NFA2 may be flat areas of the display device 10.

The first non-folding area NFA1 may be located on one side of the folding area FDA, for example, a left side thereof. The second non-folding area NFA2 may be located on the other side of the folding area FDA, for example, a right side thereof. The folding area FDA is an area defined by the first folding line FL1 and the second folding line FL2 and may be an area in which the display device 10 is bent with a predetermined curvature. The first folding line FL1 may be a boundary between the folding area FDA and the first non-folding area NFA1, and the second folding line FL2 may be a boundary between the folding area FDA and the second non-folding area NFA2.

As illustrated in FIGS. 1 and 2, the first folding line FL1 and the second folding line FL2 may extend in the second direction DR2, and in this case, the display device 10 may be folded based on the second direction DR2. Accordingly, because a length of the display device 10 in the first direction DR1 may be reduced by approximately half, it may be convenient for the user to carry the display device 10.

The first non-folding area NFA1 may be located on one side of the folding area FDA, for example, a left side thereof. The second non-folding area NFA2 may be located on the other side of the folding area FDA, for example, a right side thereof. Here, the left side may refer to one side in the first direction DR1, and the right side may refer to the other side in the first direction DR1.

When the first folding line FL1 and the second folding line FL2 extend in the second direction DR2 as illustrated in FIGS. 1 and 2, a length of the folding area FDA in the second direction DR2 may be longer than a length thereof in the first direction DR1. In addition, a length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Each of the display area DA and the non-display area NDA may overlap at least one of the folding area FDA, the first non-folding area NFA1, or the second non-folding area NFA2. It is illustrated in FIGS. 1 and 2 that the display area DA and the non-display area NDA each overlap the folding area FDA, the first non-folding area NFA1, and the second non-folding area NFA2.

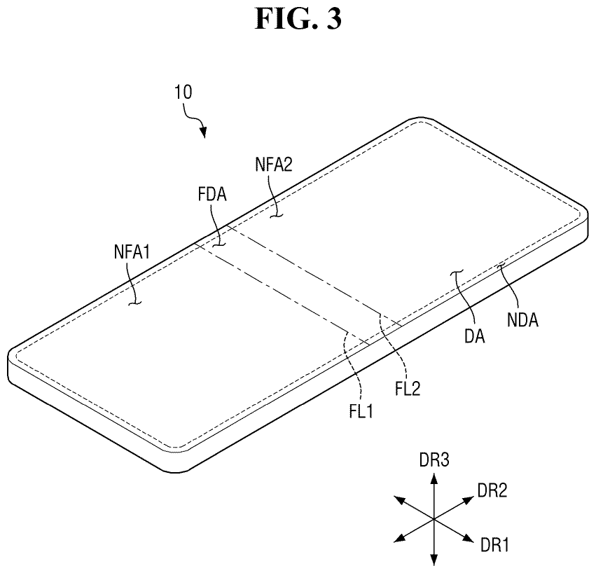

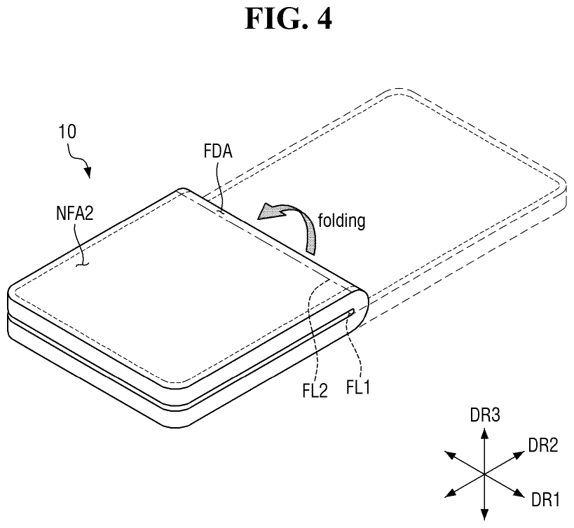

FIG. 3 is a perspective view illustrating a state in which a display device according to some embodiments is unfolded. FIG. 4 is a perspective view illustrating a state in which a display device according to some embodiments is folded.

Referring to FIGS. 3 and 4 together with FIGS. 1 and 2, FIG. 3 illustrates a first state of the display device 10 in which the display device 10 is unfolded without being folded at the folding lines FL1 and FL2, and FIG. 4 illustrates a second state of the display device 10 in which the display device 10 is folded at the folding lines FL1 and FL2.

The embodiments illustrated with respect to FIGS. 3 and 4 are different from the embodiments illustrated with respect to FIGS. 1 and 2 only in that the length of the display device 10 in the second direction DR2 is reduced by approximately half because the first folding line FL1 and the second folding line FL2 extend in the first direction DR1 and the display device 10 is folded in the second direction DR2. Therefore, in FIGS. 3 and 4, some descriptions that overlap with the embodiments illustrated with respect to FIGS. 1 and 2 may be omitted.

In the first state in which the display device 10 is unfolded, the long side of the display device 10 may extend along the second direction DR2, and the short side of the display device 10 may extend along the first direction DR1.

As illustrated in FIGS. 3 and 4, the first folding line FL1 and the second folding line FL2 may extend in the first direction DR1, and in this case, the display device 10 may be folded based on the first direction DR1.

The first non-folding area NFA1 may be located on one side of the folding area FDA, for example, a lower side thereof. The second non-folding area NFA2 may be located on the other side of the folding area FDA, for example, an upper side thereof. Here, the upper side may refer to one side in the second direction DR2, and the lower side may refer to the other side in the second direction DR2.

When the first folding line FL1 and the second folding line FL2 extend in the first direction DR1 as illustrated in FIGS. 3 and 4, a length of the folding area FDA in the first direction DR1 may be longer than a length thereof in the second direction DR2. In addition, a length of the first non-folding area NFA1 in the second direction DR2 may be longer than a length of the first non-folding area NFA1 in the first direction DR1. A length of the second non-folding area NFA2 in the second direction DR2 may be longer than a length of the second non-folding area NFA2 in the first direction DR1.

Hereinafter, for convenience of explanation, the embodiments illustrated with respect to FIGS. 3 and 4 will be used as an example, but embodiments according to the present disclosure are not limited thereto, and the following may also be equally applied to the embodiments illustrated with respect to FIGS. 1 and 2.

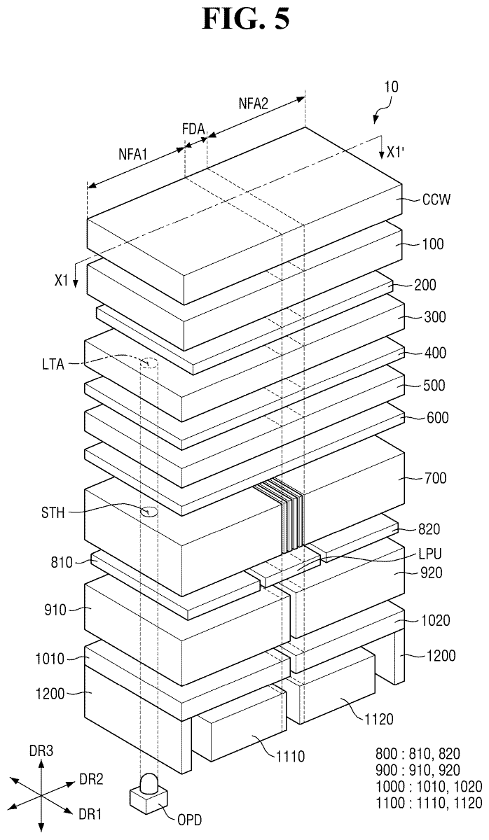

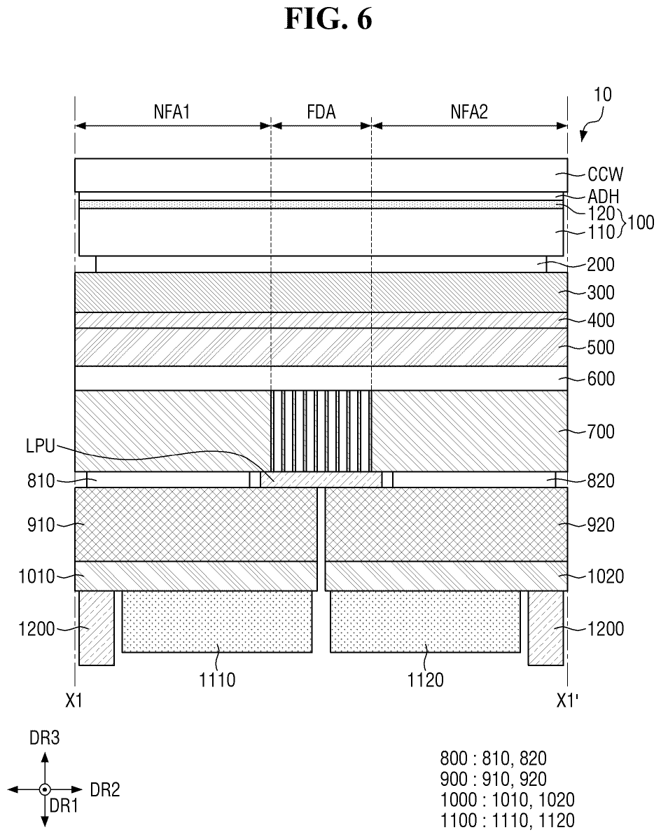

FIG. 5 is an exploded perspective view illustrating a display device according to some embodiments. FIG. 6 is a cross-sectional view taken along line X1-X1′ of FIG. 5.

Referring to FIGS. 5 and 6, the display device 10 according to some embodiments may include a cover window CCW, an upper protective member 100, a window member 200, a first adhesive member 300, a display panel 400, a panel protective member 500, a panel lower member 600, a panel support member 700, a second adhesive member 800, a lower visibility prevention member LPU, a digitizer member 900, a metal support member 1000, a buffer member 1100, and a third adhesive member 1200.

The display panel 400 may be a panel that displays an image. The display panel 400 may be an organic light emitting display panel including an organic light emitting layer, a quantum dot light emitting display panel including a quantum dot light emitting layer, an inorganic light emitting display panel using an inorganic semiconductor element as a light emitting element, and a micro light emitting display panel that uses a micro light emitting diode as a light emitting element. Hereinafter, the display panel 400 is mainly described as an organic light emitting display panel, but embodiments according to the present disclosure are not limited thereto, and the display panel 400 may include various other display panels as described above.

The display panel 400 may include a light transmissive area LTA that overlaps an optical device OPD in the third direction DR3. The optical device OPD is an optical sensor that detects light, and may be, for example, a camera sensor, a proximity sensor, and an illuminance sensor. The light transmissive area LTA may be a portion of the display area DA.

The light transmissive area LTA may include a transmissive area capable of transmitting light. Alternatively, the light transmissive area LTA may be a through hole that penetrates through the display panel. A light transmittance of the light transmissive area LTA may be higher than the light transmittance of the display area DA excluding the light transmissive area LTA. In addition, due to the transmissive area of the light transmissive area LTA, the density or integration of pixels in the light transmissive area LTA may be lower than the density or integration of pixels in the display area DA excluding the light transmissive area LTA. For example, the number of pixels per unit area in the light transmissive area LTA may be smaller than the number of pixels per unit area in the display area DA excluding the light transmissive area LTA. Alternatively, pixels per inch (PPI) in the light transmissive area LTA may be smaller than PPI in the display area DA excluding the light transmissive area LTA.

The window member 200 may be attached to the front surface of the display panel 400 using the first adhesive member 300. The window member 200 is made of a transparent material, and may be, for example, glass or plastic. For example, the window member 200 may be an ultra-thin glass (UTG) having a thickness of 0.1 mm or less or a transparent polyimide film.

The first adhesive member 300 may be located on a rear surface of the window member 200. For example, the first adhesive member 300 may be located between the window member 200 and the display panel 400. The window member 200 and the display panel 400 may be coupled to each other through the first adhesive member 300. The first adhesive member 300 may include a transparent adhesive such as pressure sensitive adhesive (PSA) or optically clear adhesive (OCA). The first adhesive member 300 may include an acrylic adhesive material.

The upper protective member 100 may be located on the front surface of the window member 200. The upper protective member 100 may be attached onto the front surface of the window member 200. The upper protective member 100 may perform at least one function of anti-scattering, shock absorption, anti-engraving, anti-fingerprint, and anti-glaring of the window member 200.

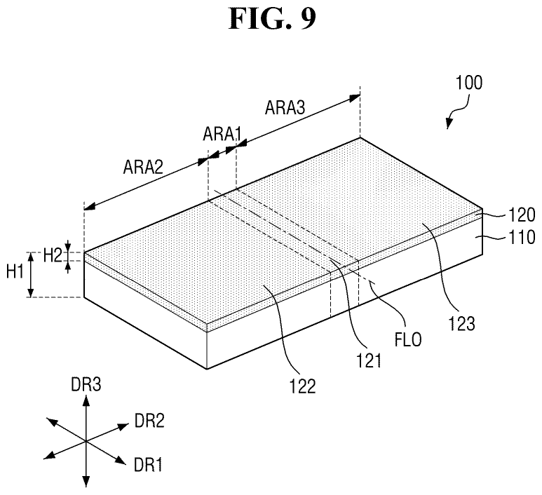

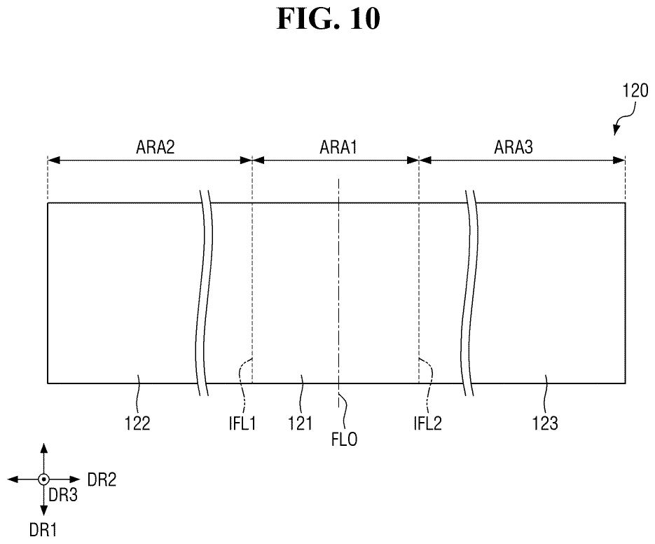

According to some embodiments, as illustrated in FIG. 6, the upper protective member 100 may include a base layer 110 and a coating layer 120 located on the base layer. The upper protective member 100 will be described later with reference to FIGS. 9 and 10.

A light blocking pattern may be formed on a rear surface of the upper protective member 100. The light blocking pattern may be located at or adjacent to an edge of the upper protective member 100. The light blocking pattern may include a light blocking material capable of blocking light. For example, the light blocking pattern may be an inorganic black pigment such as carbon black, an organic black pigment, or an opaque metal material.

The cover window CCW may be located on the upper protective member 100. The cover window CCW may be a protective film for protecting the display device 10 from external shock. The cover window CCW may be attached to or removed from the display device 10 through the adhesive member ADH. That is, the cover window CCW may be a changeable window. According to some embodiments, the cover window CCW may include, but is not limited to, at least one of flexible polyethylene terephthalate (PET) or thermoplastic polyurethane (TPU).

According to some embodiments, as illustrated in FIG. 6, the adhesive member ADH may be located on the rear surface of the cover window CCW. The adhesive member ADH may couple the cover window CCW and the upper protective member 100. According to some embodiments, the adhesive member ADH may include a transparent adhesive such as pressure sensitive adhesive (PSA) or optically clear adhesive (OCA).

The panel protective member 500 may be located on the rear surface of the display panel 400. The panel protective member 500 may serve to support the display panel 400 and protect the rear surface of the display panel 400. The panel protective member 500 may be made of plastic such as polyethylene terephthalate (PET) or polyimide. It is illustrated in the drawings that the panel protective member 500 is also located in the folding area FDA of the display device 10, but the embodiments according to the present disclosure are not limited thereto. For example, the panel protective member 500 may be removed from the folding area FDA to allow the display device 10 to be smoothly folded.

The panel lower member 600 may be located on a rear surface of the panel protective member 500. The panel lower member 600 may include at least one of a light blocking layer for absorbing light incident from the outside, a buffer layer for absorbing a shock from the outside, or a heat dissipation layer for efficiently dissipating heat of the display panel 400.

The light blocking layer blocks transmission of light to prevent components located on a lower side of the light blocking layer, for example, a digitizer member 900, etc. from being visually recognized from an upper side of the display panel 400. The light blocking layer may include a light absorbing material such as a black pigment or a black dye.

The buffer layer absorbs an external shock to prevent the display panel 400 from being damaged. The buffer layer may be formed as a single layer or a plurality of layers. For example, the buffer layer may be formed of a polymer resin such as polyurethane, polycarbonate, polypropylene, or polyethylene, or may include a material having elasticity, such as a sponge made by foaming and molding rubber, urethane-based materials, or acrylic-based materials.

The heat dissipation layer may include a first heat dissipation layer including graphite or carbon nano-tube, and a second heat dissipation layer formed of a metal thin film with excellent thermal conductivity such as copper, nickel, ferrite, and silver.

According to some embodiments, the panel lower member 600 may be omitted.

The panel support member 700 may be located on the rear surface of the panel lower member 600. The panel support member 700 may be a rigid member whose shape or volume may not be easily changed by pressure from the outside. Because the panel support member 700 is located on the rear surface of the display panel 400 and is the rigid member whose shape or volume may not be easily changed due to the pressure from the outside, the panel support member 700 may support the display panel 400.

According to some embodiments, the panel support member 700 may be a polymer including carbon fiber or glass fiber. In this case, the panel support member 700 may pass the magnetic field or electromagnetic signal of the digitizer member 900 because of being formed of the polymer including carbon fiber or glass fiber. Therefore, the panel support member 700 capable of supporting the display panel 400 while not lowering a touch sensitivity of the digitizer member 900 may be provided.

According to some embodiments, the panel support member 700 may be a metal plate. For example, the panel support member 700 is a metal plate and may be made of metal or a metal alloy. The panel support member 700 may include, but is not limited to, copper (Cu), aluminum (Al), stainless steel (SUS), and/or an alloy thereof.

The panel support member 700 may include a through hole STH that overlaps the optical device OPD in the third direction DR3. The through hole STH may overlap the light transmissive area LTA of the display panel 400 in the third direction DR3. An area of the through hole STH may be greater than an area of the light transmissive area LTA. The optical device OPD may detect light incident from the front surface of the display device 10 through the light transmissive area LTA and the through hole STH.

The panel support member 700 may include a grid pattern located in the folding area FDA so as to be easily bent in the folding area FDA. As the panel support member 700 includes the grid pattern located in the folding area FDA, the panel support member 700 may be easily bent when the display device 10 is folded.

The lower visibility prevention member LPU may be located on a rear surface of the panel support member 700. The lower visibility prevention member LPU may be arranged to overlap the folding area FDA. The lower visibility prevention member LPU may be located on the same layer as the second adhesive member 800. The lower visibility prevention member LPU may be located between a second_first adhesive member 810 and a second_second adhesive member 820. The lower visibility prevention member LPU may prevent the grid pattern of the panel support member 700 from being visually recognized to the outside. The lower visibility prevention member LPU may include a flexible material to reduce folding stress of the display device 10.

The second adhesive member 800 may be located on a front surface of the digitizer member 900. For example, the second adhesive member 800 may be located between the panel support member 700 and the digitizer member 900. The panel support member 700 and the digitizer member 900 may be coupled to each other through the second adhesive member 800. The second adhesive member 800 may include a transparent adhesive such as pressure sensitive adhesive (PSA) or optically clear adhesive (OCA). The second adhesive member 800 may include an acrylic adhesive material.

In some embodiments, the second adhesive member 800 may include a second_first adhesive member 810 overlapping the first digitizer member 910 and a second_second adhesive member 820 overlapping the second digitizer member 920. The second_first adhesive member 810 and the second_second adhesive member 820 may be arranged to be spaced apart from each other with the lower visibility prevention member LPU interposed therebetween.

The digitizer member 900 may include a first digitizer member 910 and a second digitizer member 920. The first digitizer member 910 and the second digitizer member 920 may be located on the rear surface of the panel support member 700. The first digitizer member 910 and the second digitizer member 920 may be attached to the rear surface of the panel support member 700 by the second adhesive member 800.

The first digitizer member 910 and the second digitizer member 920 may not be located in the folding area FDA to reduce folding stress of the display device 10. The first digitizer member 910 may be located in the first non-folding area NFA1, and the second digitizer member 920 may be located in the second non-folding area NFA2. A gap between the first digitizer member 910 and the second digitizer member 920 may overlap the folding area FDA and may be smaller than a width of the folding area FDA. The width of the folding area FDA may be the length of the folding area FDA in the second direction DR2.

The first digitizer member 910 and the second digitizer member 920 may include electrode patterns for sensing approach or contact of an electronic pen such as a stylus pen supporting electromagnetic resonance (EMR). The first digitizer member 910 and the second digitizer member 920 may sense a magnetic field or electromagnetic signal emitted from the electronic pen based on the electrode patterns, and may determine a point where the sensed magnetic field or electromagnetic signal is greatest as touch coordinates.

Magnetic metal powder may be located on a rear surface of the first digitizer member 910 and a rear surface of the second digitizer member 920. In this case, the magnetic field or electromagnetic signal passing through the first digitizer member 910 and the second digitizer member 920 may flow into the magnetic metal powder. Therefore, due to the magnetic metal powder, the magnetic field or electromagnetic signal of the first digitizer member 910 and the second digitizer member 920 may be reduced from being emitted to the rear surface of the display device 10.

The metal support member 1000 may include a first metal support member 1010 and a second metal support member 1020. The first metal support member 1010 may be located on the rear surface of the first digitizer member 910, and the second metal support member 1020 may be located on the rear surface of the second digitizer member 920.

The first metal support member 1010 and the second metal support member 1020 may not be located in the folding area FDA to reduce folding stress of the display device 10. The first metal support member 1010 may be located in the first non-folding area NFA1, and the second metal support member 1020 may be located in the second non-folding area NFA2. A gap between the first metal support member 1010 and the second metal support member 1020 may overlap the folding area FDA and may be smaller than the width of the folding area FDA.

The first metal support member 1010 and the second metal support member 1020 may include a material having high rigidity to support the first digitizer member 910 and the second digitizer member 920. For example, the first metal support member 1010 and the second metal support member 1020 may include stainless steel such as SUS316.

The buffer member 1100 may include a first buffer member 1110 and a second buffer member 1120. The first buffer member 1110 and the second buffer member 1120 may absorb external shocks and prevent the panel support member 700 and the digitizer member 900 from being damaged. The first buffer member 1110 and the second buffer member 1120 may include a material having elasticity, such as a sponge made by foaming and molding rubber, urethane-based materials, or acrylic-based materials.

The first buffer member 1110 may be located on a rear surface of the first metal support member 1010, and the second buffer member 1120 may be located on a rear surface of the second metal support member 1020. The first buffer member 1110 and the second buffer member 1120 may not be located in the folding area FDA to reduce folding stress of the display device 10. The first buffer member 1110 may be located in the first non-folding area NFA1, and the second buffer member 1120 may be located in the second non-folding area NFA2. A gap between the first buffer member 1110 and the second buffer member 1120 may overlap the folding area FDA and may be smaller than the width of the folding area FDA.

The third adhesive member 1200 may be located on the rear surface of the first metal support member 1010 and the rear surface of the second metal support member 1020. The third adhesive member 1200 may be located at an edge of the first metal support member 1010 and an edge of the second metal support member 1020. It is illustrated in the drawing that the third adhesive member 1200 is located on both sides of the first buffer member 1110 and the second buffer member 1120, but embodiments according to the present disclosure are not limited thereto. For example, the third adhesive member 1200 may be arranged to surround the first buffer member 1110 and the second buffer member 1120.

The third adhesive member 1200 may be a waterproof tape or a waterproof member that attaches the front surface of the frame located on the rear surface of the first metal support member 1010 and the rear surface of the buffer member 1100. As a result, the third adhesive member 1200 may prevent moisture, contaminants, or dust from permeating into the display device 10. That is, a display device 10 that is waterproof and dustproof may be provided.

According to some embodiments, the third adhesive member 1200 does not surround the first buffer member 1110 and the second buffer member 1120, but may be arranged to overlap a magnet for maintaining the folding of the display device 10 in the third direction DR3. In this case, the third adhesive member 1200 may serve as a magnetic shielding member capable of shielding magnetism to prevent the digitizer member 900 or the display panel 400 from being affected by the magnetism of the magnet.

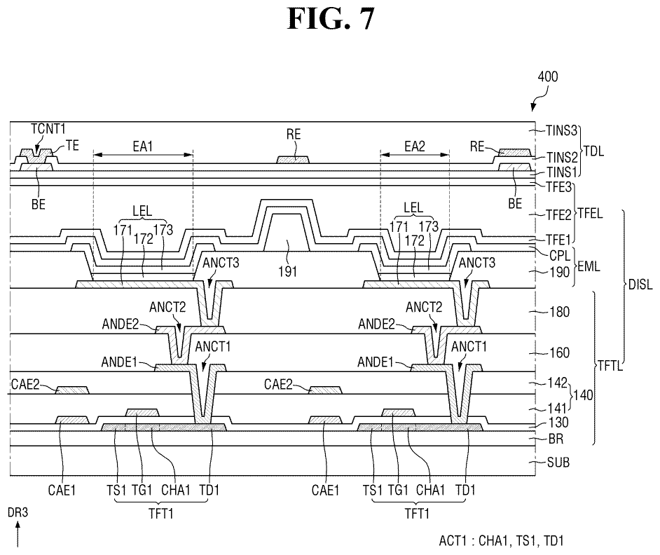

FIG. 7 is a view illustrating an example of a display panel according to some embodiments.

Referring to FIG. 7, the display panel 400 may include a substrate SUB, a display layer DISL located on the substrate SUB, and a touch sensing layer TDL located on the display layer DISL. The display layer DISL may include a thin film transistor layer TFTL, a light emitting element layer EML, and an encapsulation layer TFEL.

The thin film transistor layer TFTL may be located on the substrate SUB. The thin film transistor layer TFTL may include a barrier film BR, a thin film transistor TFT1, a first capacitor electrode CAE1, a second capacitor electrode CAE2, a first anode connection electrode ANDE1, a second anode connection electrode ANDE2, a gate insulating film 130, a first interlayer insulating film 141, a second interlayer insulating film 142, a first planarization film 160, and a second planarization film 180.

The substrate SUB may be made of an insulating material such as a polymer resin. For example, the substrate SUB may be made of polyimide. The substrate SUB may be a flexible substrate that may be bent, folded, rolled, or the like.

A barrier film BR may be located on the substrate SUB. The barrier film BR is a film for protecting thin film transistors of the thin film transistor layer TFTL and a light emitting layer 172 of the light emitting element layer EML from moisture permeating through the substrate SUB vulnerable to moisture permeation. The barrier film BR may include a plurality of inorganic films alternately stacked. For example, the barrier film BR may be formed as a multilayer film in which one or more inorganic films of a silicon nitride layer, a silicon oxynitride layer, a silicon oxide layer, a titanium oxide layer, and an aluminum oxide layer are alternately stacked.

The thin film transistor TFT1 may be located on the barrier film BR. An active layer ACT1 of the thin film transistor TFT1 may be located on the barrier film BR. The active layer ACT1 of the thin film transistor TFT1 may include polycrystalline silicon, single crystal silicon, low-temperature polycrystalline silicon, amorphous silicon, or an oxide semiconductor.

The active layer ACT1 may include a channel region CHA1, a source region TS1, and a drain region TD1. The channel region CHA1 may be a region overlapping a gate electrode TG1 in the third direction DR3 that is a thickness direction of the substrate SUB. The source region TS1 may be located on one side of the channel region CHA1, and the drain region TD1 may be located on the other side of the channel region CHA1. The source region TS1 and the drain region TD1 may be regions that do not overlap the gate electrode TG1 in the third direction DR3. The source region TS1 and the drain region TD1 may be regions having conductivity by doping a silicon semiconductor or an oxide semiconductor with ions or impurities.

The gate insulating film 130 may be located on the active layer ACT1 of the thin film transistor TFT1. The gate insulating film 130 may be formed of an inorganic film, for example, a silicon nitride layer, a silicon oxynitride layer, a silicon oxide layer, a titanium oxide layer, or an aluminum oxide layer.

The gate electrode TG1 of the thin film transistor TFT1 and the first capacitor electrode CAE1 may be located on the gate insulating film 130. The gate electrode TG1 may overlap the channel region CHA1 in the third direction DR3. It is illustrated in FIG. 7 that the gate electrode TG1 and the first capacitor electrode CAE1 are arranged to be spaced apart from each other, but the gate electrode TG1 and the first capacitor electrode CAE1 may be connected to each other and integrally formed. The gate electrode TG1 and the first capacitor electrode CAE1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first interlayer insulating film 141 may be located on the gate electrode TG1 of the thin film transistor TFT1 and the first capacitor electrode CAE1. The first interlayer insulating film 141 may be formed as an inorganic film, for example, a silicon nitride layer, a silicon oxynitride layer, a silicon oxide layer, a titanium oxide layer, or an aluminum oxide layer. The first interlayer insulating film 141 may be formed as a plurality of inorganic films.

The second capacitor electrode CAE2 may be located on the first interlayer insulating film 141. The second capacitor electrode CAE2 may overlap the first capacitor electrode CAE1 of the thin film transistor TFT1 in the third direction DR3. In addition, when the gate electrode TG1 and the first capacitor electrode CAE1 are integrally formed, the second capacitor electrode CAE2 may overlap the gate electrode TG1 in the third direction DR3. Because the first interlayer insulating film 141 has a predetermined dielectric constant, a capacitor may be formed by the first capacitor electrode CAE1, the second capacitor electrode CAE2, and the first interlayer insulating film 141 located between the first capacitor electrode CAE1 and the second capacitor electrode CAE2. The second capacitor electrode CAE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or alloys thereof.

The second interlayer insulating film 142 may be located on the second capacitor electrode CAE2. The second interlayer insulating film 142 may be formed as an inorganic film, for example, a silicon nitride layer, a silicon oxynitride layer, a silicon oxide layer, a titanium oxide layer, or an aluminum oxide layer. The second interlayer insulating film 142 may be formed as a plurality of inorganic films.

The first anode connection electrode ANDE1 may be located on the second interlayer insulating film 142. The first anode connection electrode ANDE1 may be connected to the drain region TD1 of the thin film transistor TFT1 through a first connection contact hole ANCT1 penetrating through the gate insulating film 130, the first interlayer insulating film 141, and the second interlayer insulating film 142. The first anode connection electrode ANDE1 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The first planarization film 160 for planarizing a step due to the thin film transistor TFT1 may be located on the first anode connection electrode ANDE1. The first planarization film 160 may be formed as an organic film made of an acryl resin, an epoxy resin, a phenolic resin, a polyamide resin, a polyimide resin, or the like.

The second anode connection electrode ANDE2 may be located on the first planarization film 160. The second anode connection electrode ANDE2 may be connected to the first anode connection electrode ANDE1 through a second connection contact hole ANCT2 penetrating through the first planarization film 160. The second anode connection electrode ANDE2 may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second planarization film 180 may be located on the second anode connection electrode ANDE2. The second planarization film 180 may be formed as an organic film made of an acryl resin, an epoxy resin, a phenolic resin, a polyamide resin, a polyimide resin, or the like.

The light emitting element layer EML including light emitting elements LEL and a bank 190 may be located on the second planarization film 180. Each of the light emitting elements LEL includes a pixel electrode 171, a light emitting layer 172, and a common electrode 173.

The pixel electrode 171 may be located on the second planarization film 180. The pixel electrode 171 may be connected to the second anode connection electrode ANDE2 through a third connection contact hole ANCT3 penetrating through the second planarization film 180.

In a top emission structure that emits light in a direction of the common electrode 173 with respect to the light emitting layer 172, the pixel electrode 171 may be formed of a metal material having high reflectance, such as a stacked structure (Ti/Al/Ti) of aluminum (Al) and titanium (Ti), a stacked structure (ITO/AI/ITO) of aluminum (Al) and indium tin oxide (ITO), an APC alloy, and a stacked structure (ITO/APC/ITO) of an APC alloy and ITO. The APC alloy is an alloy of silver (Ag), palladium (Pd), and copper (Cu).

The bank 190 may be formed to partition the pixel electrode 171 on the second planarization film 180 to define light emitting portions EA1 and EA2. The bank 190 may be arranged to cover an edge of the pixel electrode 171. The bank 190 may be formed as an organic film such as an acrylic resin, an epoxy resin, a phenolic resin, a polyamide resin, or a polyimide resin.

Each of the first light emitting portion EA1 and the second light emitting portion EA2 refers to each area in which the pixel electrode 171, the light emitting layer 172, and the common electrode 173 are sequentially stacked and holes from the pixel electrode 171 and electrons from the common electrode 173 are combined with each other in the light emitting layer 172 to emit light.

The light emitting layer 172 may be located on the pixel electrode 171 and the bank 190. The light emitting layer 172 may include an organic material to emit light of a predetermined color. For example, the light emitting layer 172 may include a hole transporting layer, an organic material layer, and an electron transporting layer.

The common electrode 173 may be located on the light emitting layer 172. The common electrode 173 may be arranged to cover the light emitting layer 172. The common electrode 173 may be a common layer commonly formed in the first light emitting portion EA1 and the second light emitting portion EA2.

In the top emission structure, the common electrode 173 may be formed of a transparent conductive material (TCO) such as ITO or indium zinc oxide (IZO) capable of transmitting light, or a semi-transmissive conductive material such as magnesium (Mg), silver (Ag), or an alloy of magnesium (Mg) and silver (Ag). When the common electrode 173 is formed of the semi-transmissive conductive material, light emitting efficiency may be increased by a micro cavity.

A spacer 191 may be located on the bank 190. The spacer 191 may serve to support a mask during a process of fabricating the light emitting layer 172. The spacer 191 may be formed as an organic film made of an acryl resin, an epoxy resin, a phenolic resin, a polyamide resin, a polyimide resin, or the like.

In some embodiments, the display panel 400 may further include a capping layer CPL located on the common electrode 173. The capping layer CPL may include an inorganic material. For example, the capping layer CPL may include at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride.

An encapsulation layer TFEL may be located on the common electrode 173. The encapsulation layer TFEL may include at least one inorganic film to prevent oxygen or moisture from permeating into the light emitting element layer EML. In addition, the encapsulation layer TFEL may include at least one organic film to protect the light emitting element layer EML from foreign substances such as dust. For example, the encapsulation layer TFEL may include a first encapsulation inorganic film TFE1, an encapsulation organic film TFE2, and a second encapsulation inorganic film TFE3.

The first encapsulation inorganic film TFE1 may be located on the common electrode 173, the encapsulation organic film TFE2 may be located on the first encapsulation inorganic film TFE1, and the second encapsulation inorganic film TFE3 may be located on the encapsulation organic film TFE2. The first encapsulation inorganic film TFE1 and the second encapsulation inorganic film TFE3 may be formed as a multi-film in which one or more inorganic films of a silicon nitride layer, a silicon oxynitride layer, a silicon oxide layer, a titanium oxide layer, and an aluminum oxide layer are alternately stacked. The encapsulation organic film TFE2 may be an organic film made of an acrylic resin, an epoxy resin, a phenolic resin, a polyamide resin, or a polyimide resin.

The touch sensing layer TDL may be located on the encapsulation layer TFEL. The touch sensing layer TDL includes a first touch insulating film TINS1, a connection electrode BE, a second touch insulating film TINS2, a driving electrode TE, a sensing electrode RE, and a third touch insulating film TINS3.

The first touch insulating layer TINS1 may be located on the encapsulation layer TFEL. The first touch insulating film TINS1 may be formed as an inorganic film, for example, a silicon nitride layer, a silicon oxynitride layer, a silicon oxide layer, a titanium oxide layer, or an aluminum oxide layer.

The connection electrodes BE may be located on the first touch insulating film TINS1. The connection electrode BE may be formed as a single layer or a multi-layer made of any one of molybdenum (Mo), aluminum (Al), chromium (Cr), gold (Au), titanium (Ti), nickel (Ni), neodymium (Nd), and copper (Cu), or an alloy thereof.

The second touch insulating film TINS2 may be located on the connection electrode BE. The second touch insulating film TINS2 may be formed as an inorganic film, for example, a silicon nitride layer, a silicon oxynitride layer, a silicon oxide layer, a titanium oxide layer, or an aluminum oxide layer. Alternatively, the second touch insulating film TINS2 may be formed as an organic film made of an acryl resin, an epoxy resin, a phenolic resin, a polyamide resin, a polyimide resin, or the like.

The driving electrodes TE and the sensing electrodes RE may be located on the second touch insulating film TINS2. The driving electrodes TE and the sensing electrodes RE may be formed of a single layer or a multi-layer made of any one of molybdenum (Mo), aluminum (Al), chromium (Cr), gold (Au), titanium (Ti), nickel (Ni), neodymium (Nd), and copper (Cu), or alloys thereof.

The driving electrode TE and the sensing electrode RE may overlap the connection electrode BE in the third direction DR3. The driving electrode TE may be connected to the connection electrode BE through a touch contact hole TCNT1 penetrating through the first touch insulating film TINS1.

The third touch insulating film TINS3 may be formed on the driving electrodes TE and the sensing electrodes RE. The third touch insulating film TINS3 may serve to planarize a step formed due to the driving electrodes TE, the sensing electrodes RE, and the connection electrodes BE. The third touch insulating film TINS3 may be formed as an organic film made of an acryl resin, an epoxy resin, a phenolic resin, a polyamide resin, a polyimide resin, or the like.

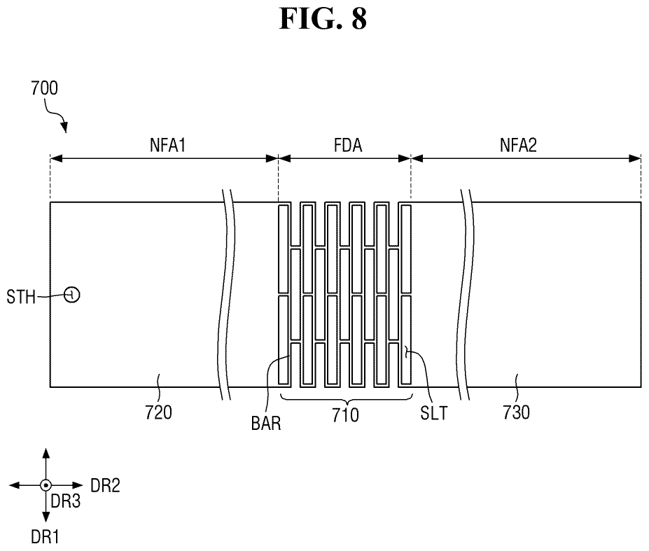

FIG. 8 is a perspective view illustrating a panel support member according to some embodiments.

Referring to FIG. 8, the panel support member 700 may include a folding portion 710, a first non-folding portion 720, and a second non-folding portion 730. The folding portion 710 may be located in the folding area FDA, the first non-folding portion 720 may be located in the first non-folding area NFA1, and the second non-folding portion 730 may be located in the second non-folding area NFA2.

In some embodiments, the folding area FDA may be an area in which the folding portion 710 is located, and the first and second non-folding areas NFA1 and NFA2 may be areas in which the first and second non-folding portions 720 and 730 are located, respectively.

The folding portion 710 may be a portion that is folded when the display device 10 is folded. The folding portion 710 may be located between the first non-folding portion 720 and the second non-folding portion 730 in the second direction DR2.

The first non-folding portion 720 and the second non-folding portion 730 may be portions that are non-folded when the display device 10 is folded. The first non-folding portion 720 may be located on one side of the folding portion 710 in the second direction DR2, and the second non-folding portion 730 may be located on the other side of the folding portion 710 in the second direction DR2.

In some embodiments, a through hole STH penetrating through the panel support member 700 may be located in the first non-folding portion 720. The through hole STH may be arranged to be adjacent to one side of the first non-folding portion 720 in the second direction DR2.

The folding portion 710 may include a grid pattern. For example, the folding portion 710 may include a plurality of bars BAR and a plurality of slits SLT located between the plurality of bars BAR.

The plurality of bars BAR may include a plurality of horizontal bars each extending in the second direction DR2 and a plurality of vertical bars each extending in the first direction DR1.

Each of the plurality of slits SLT may be a hole penetrating through the panel support member 700 in the third direction DR3. The plurality of slits SLT may each extend in the first direction DR1. For example, a length of each of the plurality of slits SLT in the first direction DR1 may be longer than a length of each of the plurality of slits SLT in the second direction DR2. The folding portion 710 may have flexibility by including the plurality of slits SLT. That is, the folding portion 710 may be stretched in the second direction DR2 when the display device 10 is folded.

FIG. 9 is a perspective view illustrating an upper protective member according to some embodiments. FIG. 10 is a plan view illustrating a coating layer according to some embodiments.

Referring to FIGS. 9 and 10, the upper protective member 100 may include a relatively flexible material to minimize or reduce a repulsive force when the display device 10 is folded. For example, the upper protective member 100 may include, but is not limited to, at least one of polyacrylate, polyethylene terephthalate (PET), polyimide (PI), cycloolefin polymer, triacetyl cellulose (TAC), polycarbonate (PC), epoxy, or polymethyl methacrylate (PMMA).

According to some embodiments, a tensile strain of the upper protective member 100 may be approximately 5% or more, but is not limited thereto. As the upper protective member 100 has flexibility, the risk of cracks occurring when the display device 10 is folded may be minimized or reduced.

According to some embodiments, a thickness H1 of the upper protective member 100 may be approximately 200 μm or less, but is not limited thereto. As the upper protective member 100 has the thickness H1 of 200 μm or less, the risk of cracks occurring when the display device 10 is folded may be minimized or reduced.

The upper protective member 100 may have sufficient hardness to protect members located on a lower side of the upper protective member 100. According to some embodiments, the Vickers hardness of the base layer 110 may be approximately 40 Hv to 50 Hv, but is not limited thereto.

The upper protective member 100 may have high transmittance and low haze so that light emitted from the light emitting layer 172 (see FIG. 7) may be emitted to the outside. For example, the transmittance of the upper protective member 100 may be approximately 85% or more, and the haze thereof may be approximately 2% or less, but are not limited thereto.

The upper protective member 100 may include a base layer 110 and a coating layer 120. For example, the upper protective member 100 may include a coating layer 120 formed by coating one surface of the base layer 110.

The base layer 110 may be a support layer. The base layer 110 may support the window member 200 (see FIG. 5) located on a lower side of the base layer 110 and the cover window CCW (see FIG. 5) located on an upper side of the base layer 110.

According to some embodiments, the base layer 110 may include at least one of polyacrylate, polyethylene terephthalate (PET), polyimide (PI), cycloolefin polymer, triacetyl cellulose (TAC), polycarbonate (PC), epoxy, or polymethyl methacrylate (PMMA) as described above.

The coating layer 120 may be located on the base layer 110. The coating layer 120 may be a layer formed by coating an upper surface of the base layer 110. According to some embodiments, the coating layer 120 may include, but is not limited to, at least one of silicone-based materials such as polysilazane and polysiloxane, acrylic-based materials, epoxy-based materials, or polyurethane.

The coating layer 120 may perform at least one function of anti-scattering, shock absorption, anti-engraving, anti-fingerprint, and anti-glaring. The coating layer 120 may include at least one additive to perform the above-mentioned functions. For example, the additive may be an anti-fingerprint (AF) additive, but is not limited thereto.

In some embodiments, a thickness H2 of the coating layer 120 may be approximately 1 μm to 20 μm. In the display device 10 according to some embodiments, as the thickness H2 of the coating layer 120 is 1 μm or more, the coating layer 120 may have sufficient hardness to prevent damage thereof. In addition, as the coating layer 120 has the thickness H2 of 20 μm or less, the occurrence of cracks when the display device 10 is folded may be minimized or reduced.

The coating layer 120 may be arranged over an entire surface of the base layer 110. In some embodiments, the coating layer 120 may be formed by a roll to roll process, but is not limited thereto.

The coating layer 120 may include a first portion 121, a second portion 122, and a third portion 123.

The first portion 121 may be located between the second portion 122 and the third portion 123 in the second direction DR2. The first portion 121 may be located at a center of the coating layer 120 in the second direction DR2. The first portion 121 may extend in the first direction DR1.

A folding central axis FL0 may be located at a center of the first portion 121. The folding central axis FL0 may be a center line located between the first folding line FL1 and the second folding line FL2.

The second portion 122 may be located on one side of the first portion 121, and the third portion 123 may be located on the other side of the first portion 121. For example, the second portion 122 may be located on the other side of the first portion 121 in the second direction DR2, and the third portion 123 may be located on one side of the first portion 121 in the second direction DR2.

A first boundary line IFL1 may be positioned at a boundary between the first portion 121 and the second portion 122, and a second boundary line IFL2 may be positioned at a boundary between the first portion 121 and the third portion 123.

In some embodiments, the upper protective member 100 may include a first area ARA1, a second area ARA2, and a third area ARA3. The first area ARA1 may be an area in which the first portion 121 is located, the second area ARA2 may be an area in which the second portion 122 is located, and the third area ARA3 may be an area in which the third portion 123 is located.

In the display device 10 according to some embodiments, a water contact angle of the first portion 121 may be different from the water contact angles of the second and third portions 122 and 123. For example, the water contact angle of the first portion 121 may be smaller than the water contact angles of the second and third portions 122 and 123.

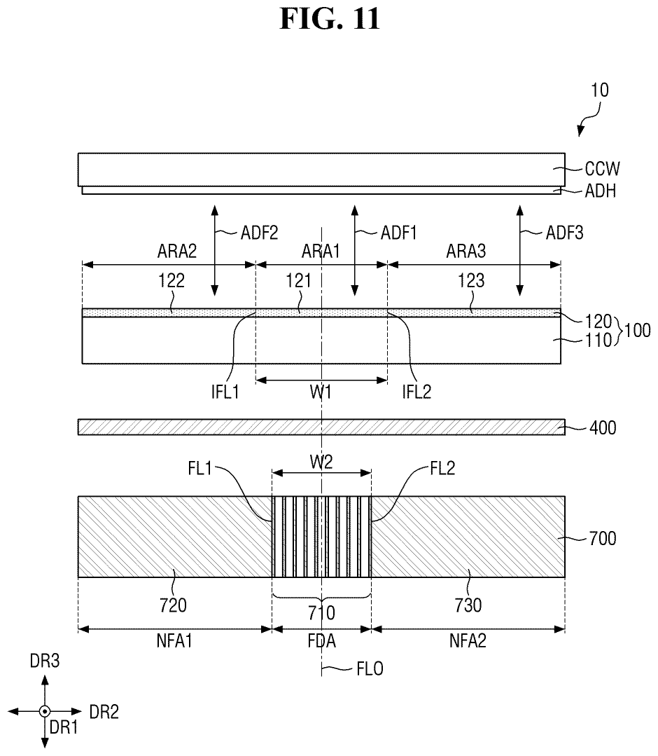

Accordingly, in the display device 10 according to some embodiments, a first adhesive force ADF1 (see FIG. 11), which is an adhesive force between the first portion 121 and the adhesive member ADH (see FIG. 11) may be different from second and third adhesive forces ADF2 and ADF3 (see FIG. 11), which are adhesive forces between the second and third portions 122 and 123 and the adhesive member ADH (see FIG. 11). For example, the first adhesive force ADF1 (see FIG. 11) may be greater than the second and third adhesive forces ADF2 and ADF3 (see FIG. 11).

This will be described in detail later with reference to FIG. 11.

FIG. 11 is a cross-sectional view illustrating some layers of a display device according to some embodiments.

Referring to FIG. 11, in the display device 10 according to some embodiments, the coating layer 120 may perform at least one function of anti-scattering, shock absorption, anti-engraving, anti-fingerprint, and anti-glaring as described above. The coating layer 120 may include at least one additive to perform the above-mentioned functions. Accordingly, the coating layer 120 including the additive may become relatively hydrophobic.

Meanwhile, the cover window CCW located on the upper protective member 100 may be coupled to the upper protective member 100 by the adhesive member ADH. The adhesive force between the adhesive member ADH and the upper protective member 100 may be weakened by the relatively hydrophobic coating layer 120.

As the display device 10 repeats folding and unfolding operations, a lifting phenomenon may more easily occur in the cover window CCW located in the folding area FDA than in the cover window CCW located in the first and second non-folding areas NFA1 and NFA2 due to the weakened adhesive force.

The display device 10 according to the present embodiments may minimize or reduce the lifting phenomenon of the cover window CCW by making the adhesive force of the first portion 121 greater than those of the second and third portions 122 and 123.

Specifically, a water contact angle of the first portion 121 of the coating layer 120 may be different from the water contact angles of the second and third portions 122 and 123. For example, the water contact angle of the first portion 121 may be smaller than the water contact angles of the second and third portions 122 and 123. According to some embodiments, the water contact angle of the first portion 121 may be approximately 90 degrees to 105 degrees. According to some embodiments, the water contact angle of the first portion 121 may be approximately 100 degrees. According to some embodiments, the water contact angle of the second and third portions 122 and 123 may be approximately 110 degrees or more.

The specific measurement method of the water contact angle will be described with reference to the experimental examples to be described later.

Accordingly, in the display device 10 according to some embodiments, a first adhesive force ADF1, which is an adhesive force between the first portion 121 and the adhesive member ADH may be different from second and third adhesive forces ADF2 and ADF3, which are adhesive forces between the second and third portions 122 and 123 and the adhesive member ADH. For example, the first adhesive force ADF1 may be greater than the second and third adhesive forces ADF2 and ADF3.

According to some embodiments, the first adhesive force ADF1 may be 3 to 8 times the second and third adhesive forces ADF2 and ADF3. For example, the first adhesive force ADF1 may be approximately 800 gf/in to 1600 gf/in, and the second and third adhesive forces ADF2 and ADF3 may be approximately 100 gf/in to 400 gf/in.

As an example, at a room temperature of 25° C., the first adhesive force ADF1 may be approximately 1000 gf/in or more, and the second and third adhesive forces ADF2 and ADF3 may be approximately 400 gf/in or less. As another example, at a room temperature of 60° C., the first adhesive force ADF1 may be approximately 800 gf/in or more, and the second and third adhesive forces ADF2 and ADF3 may be approximately 200 gf/in or less.

Herein, the adhesive force may be a value measured when two members are coupled at a room temperature of 25±3° C., and the coupled two members are left for 30±5 minutes and are then peeled at a peeling angle of 180° and a peeling velocity of 300 mm/min.

As such, the display device 10 according to the present embodiments may minimize or reduce the lifting phenomenon of the cover window CCW by making the adhesive force of the first portion 121 greater than those of the second and third portions 122 and 123.

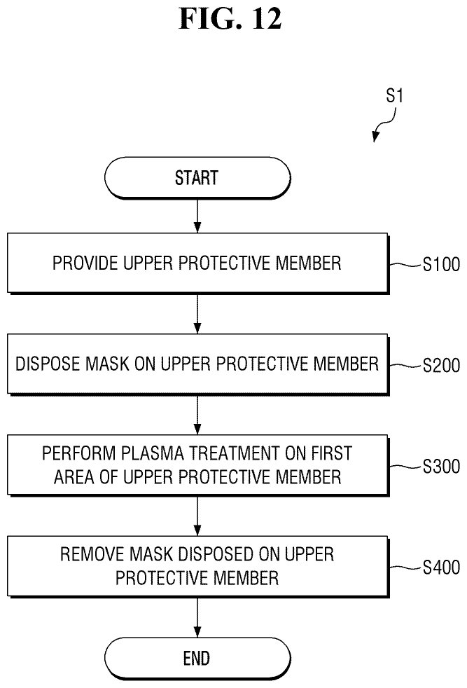

Meanwhile, a method for forming the adhesive force of the first portion 121 and the adhesive forces of the second and third portions 122 and 123 to be different from each other will be described through a method S1 for manufacturing a display device (see FIG. 12) described later.

In some embodiments, a width W1 of the first area ARA1 may be greater than a width W2 of the folding area FDA. That is, a distance between the first boundary line IFL1 and the second boundary line IFL2 may be greater than a distance between the first folding line FL1 and the second folding line FL2. For example, a width of the first portion 121 of the coating layer 120 of the upper protective member 100 may be greater than a width of the folding portion 710 of the panel support member 700.

In some embodiments, the lifting phenomenon of the cover window CCW may occur to spread not only to the folding area FDA in which the folding portion 710 is positioned, but also to portions of the first and second non-folding areas NFA1 and NFA2 adjacent to the folding area FDA. Therefore, by making the width of the first portion 121 greater than the width of the folding portion 710, the lifting phenomenon that may occur in the portions of the first and second non-folding areas NFA1 and NFA2 adjacent to the folding area FDA may be prevented.

Hereinafter, a method for manufacturing a display device according to some embodiments will be described in more detail.

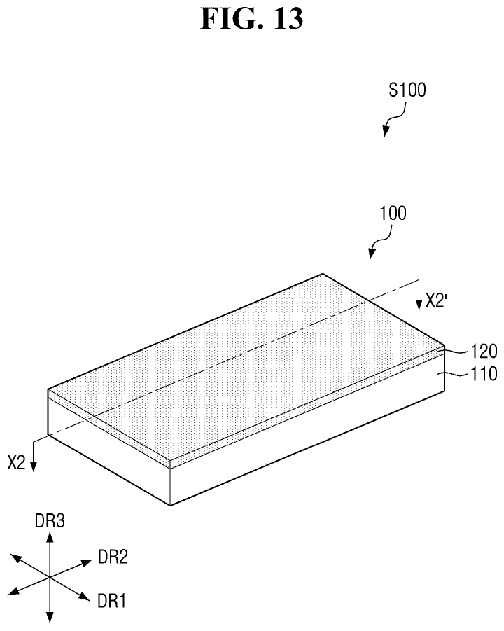

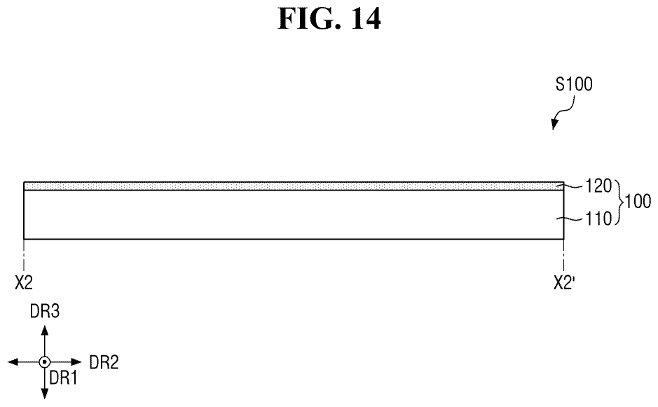

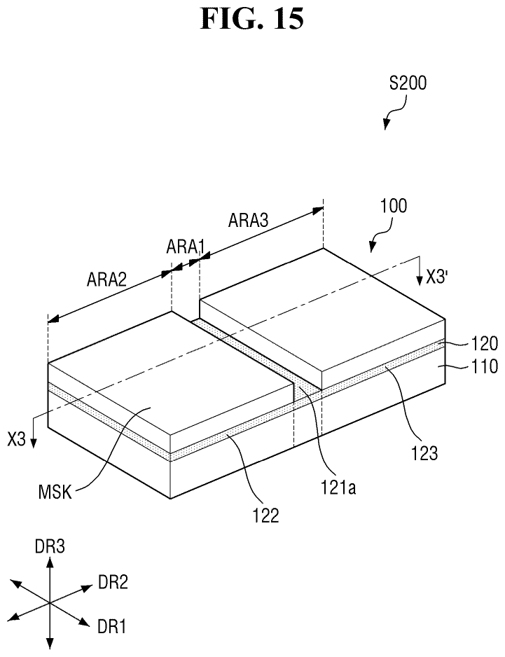

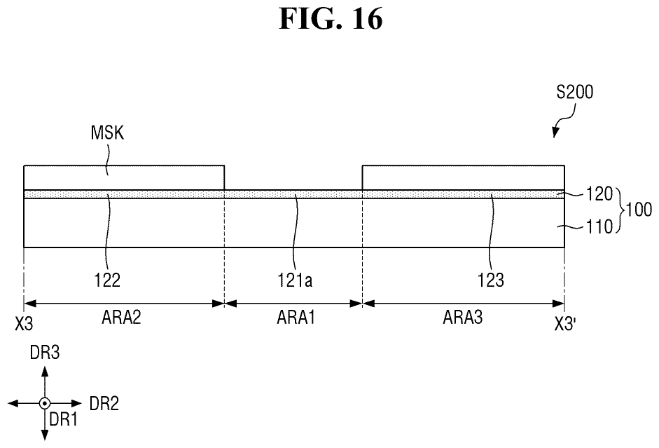

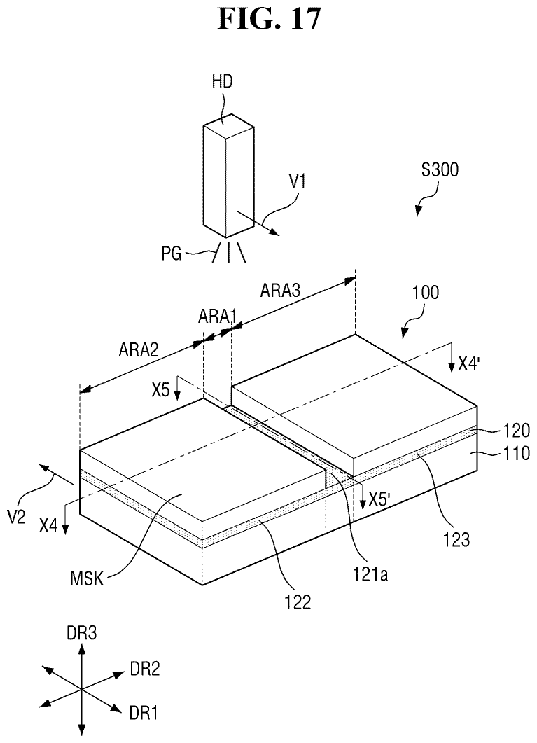

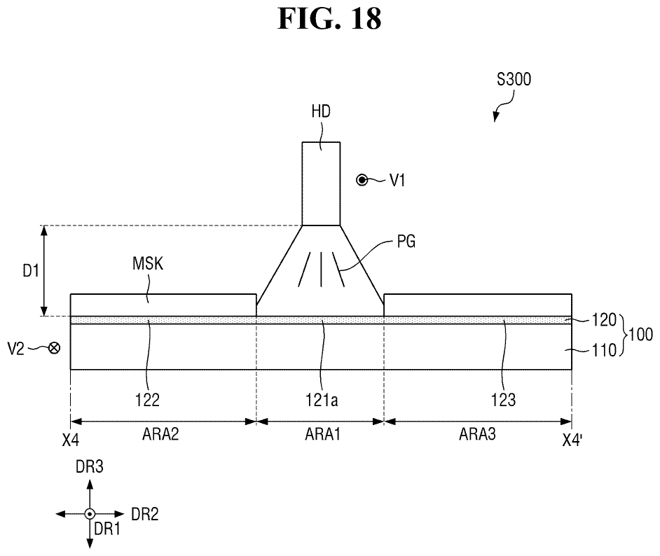

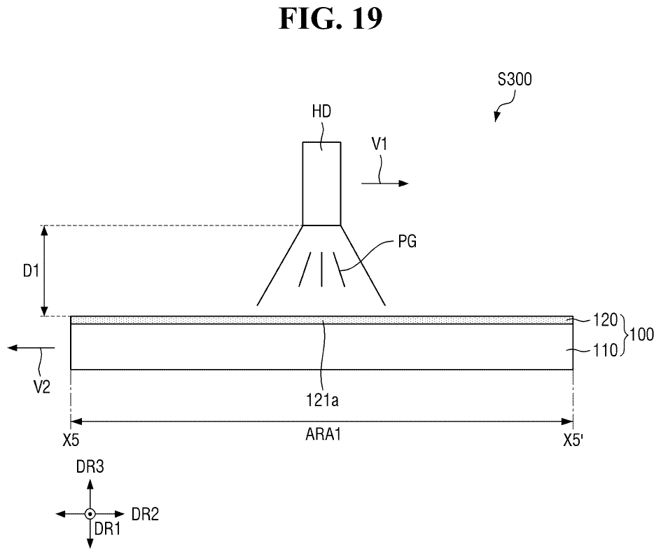

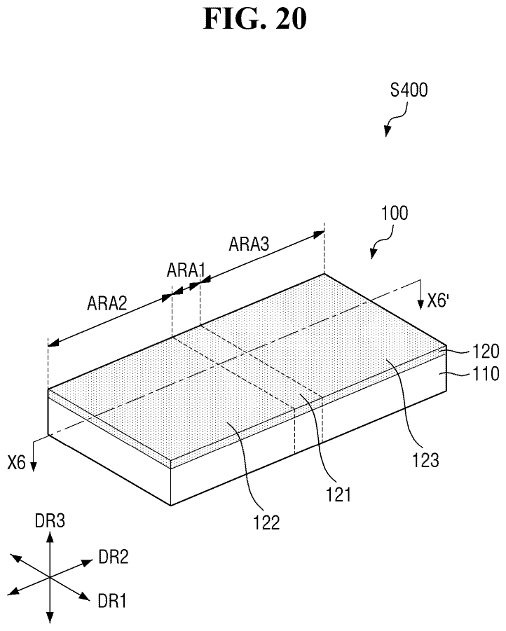

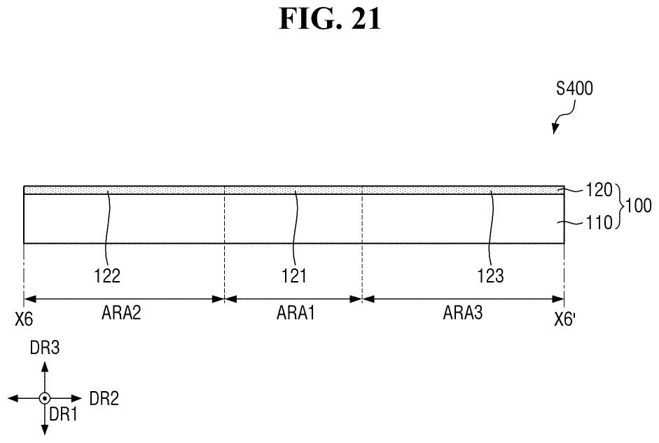

FIG. 12 is a flowchart illustrating a method for manufacturing a display device according to some embodiments. FIG. 13 is a perspective view illustrating operation S100 of FIG. 12. FIG. 14 is a cross-sectional view taken along line X2-X2′ of FIG. 13. FIG. 15 is a perspective view illustrating operation S200 of FIG. 12. FIG. 16 is a cross-sectional view taken along line X3-X3′ of FIG. 15. FIG. 17 is a perspective view illustrating operation S300 of FIG. 12. FIG. 18 is a cross-sectional view taken along line X4-X4′ of FIG. 17. FIG. 19 is a cross-sectional view taken along line X5-X5′ of FIG. 17. FIG. 20 is a perspective view illustrating operation S400 of FIG. 12. FIG. 21 is a cross-sectional view taken along line X6-X6′ of FIG. 20.

Referring to FIGS. 12 to 21, a method S1 for manufacturing a display device according to some embodiments may include providing an upper protective member (S100), arranging a mask on the upper protective member (S200), performing plasma treatment on the first area of the upper protective member (S300), and removing the mask located on the upper protective member (S400).

As illustrated in FIGS. 13 and 14, in the providing of the upper protective member (S100), the upper protective member 100 may be provided. The upper protective member 100 may include the base layer 110 and the coating layer 120 as described above.

In some embodiments, the coating layer 120 of the upper protective member 100 may be formed on one surface of the base layer 110 by a roll to roll process. When the coating layer 120 is formed through a continuous process such as a roll to roll process, the coating layer 120 may be located on an entire surface of the base layer 110.

In the method S1 for manufacturing the display device according to some embodiments, because the coating layer 120 is formed by the continuous process, a separate subsequent process may be performed to form adhesive forces of the first portion 121 and the second and third portions 122 and 123 to be different from each other. Hereinafter, the subsequent process will be described in more detail with reference to operations S200, S300, and S400.

As illustrated in FIGS. 15 and 16, in the arranging of the mask on the upper protective member (S200), a mask MSK may be located on the upper protective member 100. For example, the mask MSK may be located on at least a portion of the coating layer 120.

The mask MSK may be located on the second portion 122 and the third portion 123 of the coating layer 120. The mask MSK may not be located on a first preliminary portion 121a of the coating layer 120.

As illustrated in FIGS. 17 to 19, in the performing of the plasma treatment on the first area of the upper protective member (S300), a head HD may be positioned on the upper protective member 100. The head HD may be a plasma treatment device. The head HD may perform the plasma treatment on the first preliminary portion 121a on which the mask MSK is not located using a plasma gas PG.

For example, the head HD may move to one side in the first direction DR1 with a first velocity V1, and the upper protective member 100 may move to the other side in the first direction DR1 with a second velocity V2. According to some embodiments, only one of the head HD and the upper protective member 100 may also be moved.

The head HD may inject the plasma gas PG into the first preliminary portion 121a at the same time as it moves. In some embodiments, the plasma gas PG may be nitrogen (N₂) gas, oxygen (O₂) gas, hydrogen (H₂) gas, fluorine (F₂) gas, etc., but is not limited thereto.

Radicals included in the plasma gas PG may react with molecules included in a surface of the first preliminary portion 121a, thereby making the first preliminary portion 121a hydrophilic and forming the first portion 121. The first portion 121 may become hydrophilic to reduce the water contact angle, and the adhesive force of the adhesive member ADH (FIG. 11) to the first portion 121 may be relatively improved.

For example, the oxygen radicals included in the plasma gas PG may combine with carbon and hydrogen atoms included in the first portion 121 to form an oxygen layer on the surface of the first portion 121.

In the method S1 for manufacturing the display device according to some embodiments, a change in the water contact angle of the first portion 121 due to the plasma treatment may be affected by a relative velocity between the first velocity V1 of the head HD and the second velocity V2 of the upper protective member 100. Therefore, in order for the water contact angle of the first portion 121 to be within the above-mentioned range, the relative velocity between the first velocity V1 of the head HD and the second velocity V2 of the upper protective member 100 is approximately 3 m/min to 8 m/min.

Specific plasma treatment conditions will be described with reference to experimental examples to be described later.

As illustrated in FIGS. 20 and 21, in the removing of the mask located on the upper protective member (S400), the mask MSK located on the coating layer 120 of the upper protective member 100 may be removed.

According to the display device 10 according to some embodiments, the water contact angle of the first portion 121 may be formed to be different from the water contact angles of the second and third portions 122 and 123 through the plasma treatment. Accordingly, by forming the adhesive force of the first portion 121 to be different from those of the second and third portions 122 and 123, the lifting phenomenon of the cover window CCW (see FIG. 11) located on the first portion 121 may be minimized or reduced.

Hereinafter, various embodiments and comparative examples will be described according to the experimental results of specific experimental examples.

### Application Example: Plasma Treatment Method

As illustrated in FIGS. 17 to 19, a plasma treatment process may be affected by a discharge power of the head HD, a discharge gap, a discharge gas flow rate, and a relative velocity between the head HD and the upper protective member 100. The discharge gap refers to a distance D1 between the head HD and the coating layer 120.

In some embodiments, the discharge power of the head HD may be approximately 1 kW to 5 kW, the discharge gap may be approximately 1 mm to 50 mm, and the discharge gas flow rate may be approximately 100 LPM to 1000 LPM.

In the experimental example of the specification, a case in which the discharge power of the head HD is 3 kW, the discharge gap is 10 mm, the discharge gas flow rate is 400 LPM, and the type of discharge gas is nitrogen (N₂) gas will be described as an example.

Changes in the water contact angle and adhesive force of the coating layer 120 due to the plasma treatment may be largely affected by the relative velocity between the head HD and the upper protective member 100. Therefore, in the experimental examples of the present disclosure, the changes in the water contact angle and adhesive force of the coating layer 120 were observed by constantly controlling the discharge power, discharge gap, and discharge gas flow rate, and varying the relative velocity between the head HD and the upper protective member 100.

### Experimental Example 1: Whether Water Contact Angle Changes and CW Lifting Occurs Depending on Plasma Treatment Method

TABLE 1

| | | Water Contact | Water Contact | | Whether CW is |
|---|---|---|---|---|---|
| | | Angle (°) of | Angle (°) of First | | Lifted When |
| | Relative | Second and | Portion 121 | | Folded |
| | Velocity | Third Portions | In 1 | After 24 | 150,000 |
| Classification | (m/min) | 122 and 123 | hour | hours | Times |
| First | 6 | 111.1 | 103.3 | 105.0 | Not Occurred |
| Embodiment | | | | | |
| Second | 3 | | 85.5 | 100.6 | Not Occurred |
| Embodiment | | | | | |
| First | 12 | | 109.6 | 109.1 | Occurred |
| Comparative | | | | | |
| Example | | | | | |
| Second | 9 | | 106.3 | 107.0 | Occurred |
| Comparative | | | | | |
| Example | | | | | |

In the present disclosure, the water contact angle means a value measured under standard conditions at the test site specified in JIS Z 8703. The standard conditions of the test site specified in JIS Z 8703 mean a room temperature of 22±2° C. and a normal humidity of 55±5% RH. A capacity of a water droplet used to measure the water contact angle may be approximately 3 μl, and a falling velocity of the water droplet may be approximately 2.67 m/s. The water contact angle may be a value measured according to a sessile drop method.

As illustrated in Table 1, when the relative velocity between the head HD and the upper protective member 100 was 3 m/min to 8 m/min, the lifting phenomenon of the cover window CCW did not occur when the display device 10 was folded 150,000 times.

For example, the first and second embodiments were subjected to plasma treatment at relative velocities of 6 m/min and 3 m/min, respectively, and the first and second comparative examples were subjected to plasma treatment at relative velocities of 12 m/min and 9 m/min, respectively.

In the first and second embodiments, the water contact angles measured within 1 hour after the plasma treatment were low at 103.3° and 85.5°, respectively, and even after 24 hours, the water contact angle was maintained within 105°, which not causes lifting of the cover window CCW.

On the other hand, in the first and second comparative examples, the water contact angles measured within 1 hour after the plasma treatment were high at 109.6° and 106.3°, respectively, and even after 24 hours, the water contact angle remained greater than 105°, which causes lifting of the cover window CCW.

In the display device 10 according to some embodiments, the lifting phenomenon of the cover window CCW may be prevented by maintaining the water contact angle of the first portion 121 within approximately 105 degrees. In addition, in the method S1 for manufacturing the display device according to some embodiments, the range of the water contact angle may be achieved by maintaining the relative velocity between the head HD and the upper protective member 100 within 8 m/min.

### Experimental Example 2: Whether Removal Mark Occurs During Rework According to Water Contact Angle

TABLE 2

| | Water Contact Angle (°) | Whether Removal Mark |
|---|---|---|
| Classification | of First Portion 121 | Occurs During Rework |
| Third Embodiment | 90.1 | Not Occurred |
| Fourth Embodiment | 105.0 | Not Occurred |
| Third Comparative | 109.1 | Not Occurred |
| Example | | |
| Fourth Comparative | 85.5 | Occurred |
| Example | | |

Table 2 is a table indicating whether a removal mark occurred on the upper protective member 100 during a process of peeling off the cover window CCW after attaching the cover window CCW to the upper protective member 100. In some embodiments, during the process of attaching the cover window CCW, there may be a case where the cover window CCW attached to the upper protective member 100 needs to be peeled off and then reattached due to some reason such as alignment. During such a rework process, if the removal mark remains on the upper protective member 100 due to peeling of the cover window CCW, it may cause poor quality of the display device 10. Therefore, it may be desirable to maintain an adhesive force to the extent that no removal mark remains during the rework process.

As illustrated in Table 2, when the water contact angle of the first portion 121 was 90° or more, no removal marks occurred as in the third embodiments, fourth embodiments, and third comparative example. On the other hand, in the fourth comparative example, as the first portion 121 had the water contact angle of less than 90 degrees, the removal marks occurred during the rework process due to a high adhesive force.

Meanwhile, in the case of the third comparative example, no removal marks occurred, but according to the results of Experimental Example 1, because it had the water contact angle exceeding 105 degrees, the adhesive force was low and the lifting phenomenon of the cover window CCW may occur.

In the display device 10 according to some embodiments, the occurrence of the removal marks may be prevented during the rework process of the cover window CCW by maintaining the water contact angle of the first portion 121 at approximately 90 degrees or more. In addition, in the method S1 for manufacturing the display device according to some embodiments, the range of the water contact angle may be achieved by maintaining the relative velocity between the head HD and the upper protective member 100 within 3m/min or more.

In concluding the detailed description, those skilled in the art will appreciate that many variations and modifications can be made to the disclosed embodiments without substantially departing from the principles of the present disclosure. Therefore, the disclosed embodiments of the invention are used in a generic and descriptive sense only and not for purposes of limitation.

What is claimed is:

1. A display device comprising:
a display panel including a folding area and a non-folding area on one side of the folding area; and
an upper protective member on a first surface of the display panel and including a coating layer,
wherein the coating layer includes:
a first portion overlapping the folding area; and
a second portion on one side of the first portion,
wherein a contact angle of the first portion is different from a contact angle of the second portion.

2. The display device of claim 1, wherein the contact angle of the first portion is smaller than the contact angle of the second portion.

3. The display device of claim 2, wherein the contact angle of the first portion is in a range of 90 degrees to 105 degrees.

4. The display device of claim 3, wherein the contact angle of the second portion is 110 degrees or more.

5. The display device of claim 1, further comprising:
a cover window on the upper protective member; and
an adhesive member between the cover window and the upper protective member,
wherein a first adhesive force, which is an adhesive force between the first portion and the adhesive member, is different from a second adhesive force, which is an adhesive force between the second portion and the adhesive member.

6. The display device of claim 5, wherein the first adhesive force is greater than the second adhesive force.

7. The display device of claim 6, wherein the first adhesive force is in a range of 3 to 8 times the second adhesive force.

8. The display device of claim 1, further comprising a panel support member on a second surface of the display panel,
wherein the panel support member includes a folding portion in the folding area and a non-folding portion in the non-folding area, and
wherein a width of the first portion is greater than a width of the folding portion.

9. The display device of claim 1, wherein the upper protective member includes at least one of polyacrylate, polyethylene terephthalate, polyimide, cycloolefin polymer, triacetyl cellulose, polycarbonate, epoxy, or polymethyl methacrylate.

10. The display device of claim 1, wherein the upper protective member has a transmittance of 85% or more and a haze of 2% or less.

11. The display device of claim 1, wherein the coating layer includes at least one of a silicone-based material, an acrylic-based material, an epoxy-based material, or polyurethane.

12. The display device of claim 11, wherein the coating layer includes an AF additive.

13. The display device of claim 1, wherein a thickness of the upper protective member is 200 micrometers (μm) or less.

14. The display device of claim 13, wherein a thickness of the coating layer is in a range of 1 μm to 20 μm.

15. A display device comprising:
a display panel;
an upper protective member on the display panel and including a coating layer; and
a cover window on the upper protective member,
wherein the coating layer includes a first portion and a second portion on one side of the first portion,
wherein the cover window is bent in an area overlapping the first portion, and
wherein a contact angle of the first portion is different from a contact angle of the second portion.

16. The display device of claim 15, wherein the contact angle of the first portion is smaller than the contact angle of the second portion.

17. A method for manufacturing a display device, the method comprising:
providing an upper protective member including a coating layer; and
performing plasma treatment on a first portion of the coating layer excluding a second portion of the coating layer,
wherein a contact angle of the first portion is different from a contact angle of the second portion.

18. The method of claim 17, wherein in the performing of the plasma treatment, a relative velocity between a plasma treatment head and the coating layer is in a range of 3 m/min to 8 m/min.

19. The method of claim 17, wherein the contact angle of the first portion is smaller than the contact angle of the second portion.

20. The method of claim 17, wherein the coating layer is formed by a roll to roll process.
